(19) United States
(12) Patent Application Publication
(10) Pub. No.: US 2025/0266296 A1
(43) Pub. Date: Aug. 21, 2025

(54) INTEGRATED METHODS OF MANUFACTURING LOGIC DEVICES AND MEMORY DEVICES

(71) Applicant: Applied Materials, Inc., Santa Clara, CA (US)

(72) Inventors: Jiajie Cen, San Jose, CA (US); Shashank Sharma, Los Gatos, CA (US); Shiyu Yue, Sunnyvale, CA (US); Yongqian Gao, Sunnyvale, CA (US); Zhen Liu, Santa Clara, CA (US); Gaurav Thareja, Santa Clara, CA (US); Shankar Muthukrishnan, San Jose, CA (US)

(73) Assignee: Applied Materials, Inc., Santa Clara, CA (US)

(21) Appl. No.: 19/053,759

(22) Filed: Feb. 14, 2025

Related U.S. Application Data
(60) Provisional application No. 63/553,877, filed on Feb. 15, 2024.

(51) Int. Cl. H01L 21/768; H01L 21/285; H01L 21/321; H01L 23/532

(52) U.S. Cl. CPC H01L 21/76886; H01L 21/28568; H01L 21/321; H01L 23/53257

(57) ABSTRACT

Methods of forming molybdenum-containing layers as part of a semiconductor device fabrication process are described. The methods include forming a molybdenum-containing layer on a substrate in a cluster tool; treating the molybdenum-containing layer with a plasma in situ; annealing the treated molybdenum-containing layer in situ to form an annealed molybdenum-containing layer having a resistivity that is in a range of from 50% to 90% less than a resistivity of the molybdenum-containing layer.

### CROSS-REFERENCE TO RELATED APPLICATIONS

This application claims priority to U.S. Provisional Application No. 63/553,877, filed Feb. 15, 2024, the entire disclosure of which is hereby incorporated by reference herein.

### TECHNICAL FIELD

Embodiments of the disclosure generally relate to semiconductor device fabrication processes. More particularly, embodiments of the disclosure are directed to integrated methods of forming and processing molybdenum-containing layers without breaking vacuum.

### BACKGROUND

The advancing complexity of semiconductor devices, such as logic devices and memory devices, is placing stringent demands on currently used deposition techniques. Molybdenum has attractive material and conductive properties and has found broad applicability in semiconductor devices and fabrication processes.

For example, molybdenum-containing layers may be used as low resistivity electrical connections in the form of vertical interconnects and/or horizontal interconnects through which current flows, as vias between adjacent metal layers, and/or as contacts between a first metal layer and one or more devices on a substrate.

Annealing processes are typically performed to increase density of deposited metal layers, such as molybdenum-containing layers, and reduce resistivity. However, it has been found that exposing metallic materials to air can result in a thin layer of metal oxide being formed on the surface of the metal. This surface layer of metal oxide can interfere with subsequent processing steps and increase resistivity of the metal layer. For example, when a substrate having a molybdenum-containing layer formed thereon is exposed to air during transfer of the substrate to an annealing chamber ex situ, a thin layer of molybdenum oxide forms on the molybdenum-containing layer. The metal oxide layer and its increased resistivity works against a goal of annealing processes: to reduce resistivity.

Accordingly, there is a need for methods of preventing metal oxide formation and forming molybdenum-containing layers having reduced resistivity.

### SUMMARY

One or more embodiments of the disclosure are directed to a processing method comprising: forming a molybdenum-containing layer on a substrate in a cluster tool. The molybdenum-containing layer has a first resistivity value in a range of from greater than or equal to 100 μΩ-cm to less than or equal to 500 μΩ-cm. The processing method further comprises: treating the molybdenum-containing layer with a plasma in situ for a time period in a range of from 0.1 seconds to 2 seconds to reduce the first resistivity value and to form a treated molybdenum-containing layer having a second resistivity value; and annealing the treated molybdenum-containing layer in situ to reduce the second resistivity value and to form an annealed molybdenum-containing layer having a third resistivity value that is in a range of from 50% to 90% less than the first resistivity value.

Additional embodiments of the disclosure are directed to methods of manufacturing semiconductor devices. In one or more embodiments, the methods comprise forming a molybdenum-containing layer on a substrate in a cluster tool. In some embodiments, the substrate includes at least one feature defining a gap having sidewalls comprising a low-κ dielectric material and a bottom comprising a metallic material, the molybdenum-containing layer fills the gap and has a first resistivity value in a range of from greater than or equal to 100 μΩ-cm to less than or equal to 500 μΩ-cm. The methods further comprise: treating the molybdenum-containing layer with a plasma in situ for a time period in a range of from 0.1 seconds to 2 seconds to reduce the first resistivity value and to form a treated molybdenum-containing layer having a second resistivity value; and annealing the treated molybdenum-containing layer in situ to reduce the second resistivity value and to form an annealed molybdenum-containing layer having a third resistivity value that is in a range of from 50% to 90% less than the first resistivity value. In some embodiments, the annealing is performed at a temperature in a range of from 200° C. to 1000° C. for a time in a range of from 5 seconds to 20 minutes.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a process flow diagram of a method in accordance with one or more embodiments of the disclosure;

FIG. 2A illustrates a cross-sectional schematic view of a substrate having a molybdenum-containing layer formed thereon in accordance with one or more embodiments of the disclosure;

FIG. 2B illustrates a cross-sectional schematic view of treating the molybdenum-containing layer of FIG. 2A with a plasma in situ to form a treated molybdenum-containing layer in accordance with one or more embodiments of the disclosure;

FIG. 2C illustrates a cross-sectional schematic view of annealing the treated molybdenum-containing layer of FIG. 2B in situ to form an annealed molybdenum-containing layer in accordance with one or more embodiments of the disclosure;

FIG. 3A illustrates a cross-sectional schematic view of a substrate including at least one feature defining a gap having sidewalls and a bottom in accordance with one or more embodiments of the disclosure;

FIG. 3B illustrates a cross-sectional schematic view of a molybdenum-containing layer filling the gap of the substrate of FIG. 3A in accordance with one or more embodiments of the disclosure;

FIG. 3C illustrates a cross-sectional schematic view of treating the molybdenum-containing layer of FIG. 3B with a plasma in situ to form a treated molybdenum-containing layer in accordance with one or more embodiments of the disclosure;

FIG. 3D illustrates a cross-sectional schematic view of annealing the treated molybdenum-containing layer of FIG. 3C in situ to form an annealed molybdenum-containing layer in accordance with one or more embodiments of the disclosure; and

FIG. 4 illustrates a schematic top-view diagram of a multi-chamber processing system in accordance with one or more embodiments of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “about” as used herein means approximately or nearly and in the context of a numerical value or range set forth means a variation of ±15%, or less, of the numerical value. For example, a value differing by ±14%, ±10%, ±5%, ±2%, or ±1%, would satisfy the definition of about.

Spatially relative terms, such as “beneath,” “below,” “lower,” “above,” “upper” and the like, may be used herein for ease of description to describe one element's relationship to another element(s) or feature(s) as illustrated in the Figures. It will be understood that the spatially relative terms are intended to encompass different orientations of the semiconductor device in use or operation in addition to the orientation depicted in the Figures. For example, if the semiconductor device in the Figures is turned over, elements described as “below” or “beneath” other elements would then be oriented “above” the other elements. Thus, the exemplary term “below” may encompass both an orientation of above and below. The semiconductor device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments,” “some embodiments,” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in some embodiments,” “in one embodiment,” or “in an embodiment” in various places throughout this specification are not necessarily referring to the same embodiment of the disclosure. In one or more embodiments, the particular features, structures, materials, or characteristics are combined in any suitable manner.

As used in this specification and the appended claims, the term “substrate” and “wafer” are used interchangeably, both referring to a surface, or portion of a surface, upon which a process acts. It will also be understood by those skilled in the art that reference to a substrate can also refer to only a portion of the substrate, unless the context clearly indicates otherwise. Additionally, reference to “depositing on” or “forming on” a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Substrates include, without limitation, semiconductor wafers. In some embodiments, the semiconductor substrate comprises one or more of doped or undoped crystalline silicon (Si), doped or undoped crystalline silicon germanium (SiGe), doped or undoped amorphous silicon (Si), or doped or undoped amorphous silicon germanium (SiGe). Substrates may be exposed to a pretreatment process to polish, etch, reduce, oxidize, hydroxylate (or otherwise generate or graft target chemical moieties to impart chemical functionality), anneal and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

The term “on” indicates that there is direct contact between elements. The term “directly on” indicates that there is direct contact between elements with no intervening elements.

As used herein, the term “in situ” refers to processes that are all performed in the same processing chamber or within different processing chambers that are connected as part of an integrated processing system, such that each of the processes are performed without an intervening vacuum break. As used herein, the term “ex situ” refers to processes that are performed in at least two different processing chambers such that one or more of the processes are performed with an intervening vacuum break. In some embodiments, processes are performed without breaking vacuum or without exposure to ambient air.

As used herein, the terms “precursor,” “reactant,” “reactive gas,” “reactive species,” and the like are used interchangeably to refer to any gaseous species that can react with the substrate surface.

As used herein, the term “chemical vapor deposition” refers to the exposure of at least one reactive species to deposit a layer of material on the substrate surface. In some embodiments, the chemical vapor deposition (CVD) process comprises mixing the two or more reactive species in the processing chamber to allow gas phase reactions of the reactive species and deposition. In some embodiments, the CVD process comprises exposing the substrate surface to two or more reactive species simultaneously. In some embodiments, the CVD process comprises exposing the substrate surface to a first reactive species continuously with an intermittent exposure to a second reactive species. In some embodiments, the substrate surface undergoes the CVD reaction to deposit a layer having a predetermined thickness. In the CVD process, the layer can be deposited in one exposure to the mixed reactive species or can be multiple exposures to the mixed reactive species with purges between. In some embodiments, the substrate surface is exposed to the first reactive species and the second reactive species substantially simultaneously.

As used herein, “substantially simultaneously” means that most of the duration of the first reactive species exposure overlaps with the second reactive species exposure.

As used herein, the term “purging” includes any suitable purge process that removes unreacted precursor, reaction products and by-products from the process region. The suitable purge process includes moving the substrate through a gas curtain to a portion or sector of the processing region that contains none or substantially none of the reactant. In one or more embodiments, purging the processing chamber comprises applying a vacuum. In some embodiments, purging the processing region comprises flowing a purge gas over the substrate. In some embodiments, the purge process comprises flowing an inert gas. In one or more embodiments, the purge gas is selected from one or more of nitrogen (N₂), helium (He), and argon (Ar). In some embodiments, the first reactive species is purged from the reaction chamber for a time duration in a range of from 0.1 seconds to 30 seconds, from 0.1 seconds to 10 seconds, from 0.1 seconds to 5 seconds, from 0.5 seconds to 30 seconds, from 0.5 seconds to 10 seconds, from 0.5 seconds to 5 seconds, from 1 seconds to 30 seconds, from 1 seconds to 10 seconds, from 1 seconds to 5 seconds, from 5 seconds to 30 seconds, from 5 seconds to 10 seconds or from 10 seconds to 30 seconds before exposing the substrate to the second reactive species.

Plasma-enhanced chemical vapor deposition (PECVD) is a widely used technique for depositing thin films on a substrate. In a PECVD process, for example, a hydrocarbon source, such as a gas-phase hydrocarbon or a vapor of a liquid-phase hydrocarbon that have been entrained in a carrier gas, is introduced into a PECVD chamber. A plasma-initiated gas, typically helium, is also introduced into the chamber. Plasma is then initiated in the chamber to create excited CH-radicals. The excited CH-radicals are chemically bound to the surface of a substrate positioned in the chamber, forming the desired film thereon. Embodiments described herein in reference to a PECVD process can be carried out using any suitable thin film deposition system, such as a PECVD chamber in a multi-chamber processing system, e.g., a cluster tool. Any apparatus description described herein is and should not be construed or interpreted as limiting the scope of the embodiments described herein.

“Cyclical deposition” or “atomic layer deposition” (ALD) refers to the sequential exposure of two or more reactive species to deposit a layer of material on a substrate surface. The substrate, or portion of the substrate, is exposed separately to the two or more reactive species which are introduced into a reaction zone of a processing chamber. In a time-domain ALD process, exposure to each reactive species is separated by a time delay to allow each compound to adhere and/or react on the substrate surface and then be purged from the processing chamber. These reactive species are said to be exposed to the substrate sequentially. In a spatial ALD process, different portions of the substrate surface, or material on the substrate surface, are exposed simultaneously to the two or more reactive species so that any given point on the substrate is substantially not exposed to more than one reactive species simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay, a purge gas, such as argon, is introduced into the processing chamber to purge the reaction zone or otherwise remove any residual reactive species or reaction by-products from the reaction zone. Alternatively, the purge gas may flow continuously throughout the deposition process so that only the purge gas flows during the time delay between pulses of reactive species. The reactive species are alternatively pulsed until a desired layer or layer thickness is formed on the substrate surface. In either scenario, the ALD process of pulsing compound A, purge gas, compound B and purge gas is a cycle. A cycle can start with either compound A or compound B and continue the respective order of the cycle until achieving a layer with the predetermined thickness.

Plasma-enhanced atomic layer deposition (PEALD) is a widely used technique for depositing thin films on a substrate. In some examples of PEALD processes, a material may be formed from the same chemical precursors as thermal ALD processes performed without the use of plasma, but at a higher deposition rate and a lower temperature. A PEALD process, in general, provides that a reactant gas and a reactant plasma are sequentially introduced into a process chamber containing a substrate. The first reactant gas is pulsed in the process chamber and is adsorbed onto the substrate. Thereafter, the reactant plasma is pulsed into the process chamber and reacts with the first reactant gas to form a deposition material, e.g. a thin film on a substrate. Similarly to a thermal ALD process, a purge step may be conducted between the delivery of each of the reactants. Embodiments described herein in reference to a PEALD process can be carried out using any suitable thin film deposition system, such as a PEALD chamber in a multi-chamber processing system, e.g., a cluster tool. Any apparatus description described herein is and should not be construed or interpreted as limiting the scope of the embodiments described herein.

One or more of the layers deposited on the substrate or substrate surface are continuous. As used herein, the term “continuous” refers to a layer that covers an entire exposed surface without gaps or bare spots that reveal material underlying the deposited layer. A continuous layer may have gaps or bare spots with a surface area less than about 15% or less than about 10% of the total surface area of the layer.

Transistors are circuit components or elements that are often formed on semiconductor devices. Depending upon the circuit design, in addition to capacitors, inductors, resistors, diodes, conductive lines, or other elements, transistors are formed on a semiconductor device. Generally, a transistor includes a gate formed between source and drain regions. In one or more embodiments, the source and drain regions include a doped region of a substrate and exhibit a doping profile suitable for a particular application. The gate is positioned over the channel region and includes a gate dielectric interposed between a gate electrode and the channel region in the substrate.

Generally, front-end of line (FEOL) refers to the first portion of integrated circuit fabrication, including transistor fabrication, middle of line (MOL) connects the transistor and interconnect parts of a chip using a series of contact structures, and back-end of line (BEOL) refers to a series of process steps after transistor fabrication through completion of a wafer.

As used herein, the term “field effect transistor” or “FET” refers to a transistor that uses an electric field to control the electrical behavior of the device. Enhancement mode field effect transistors generally display very high input impedance at low temperatures. The conductivity between the drain and source terminals is controlled by an electric field in the device, which is generated by a voltage difference between the body and the gate of the device. The FET's three terminals are source(S), through which the carriers enter the channel; drain (D), through which the carriers leave the channel; and gate (G), the terminal that modulates the channel conductivity. Conventionally, current entering the channel at the source(S) is designated Is and current entering the channel at the drain (D) is designated I_{D}. Drain-to-source voltage is designated V_{DS}. By applying voltage to gate (G), the current entering the channel at the drain (i.e., I_{D}) can be controlled.

The metal-oxide-semiconductor field-effect transistor (MOSFET) is a type of field-effect transistor (FET). It has an insulated gate, whose voltage determines the conductivity of the device. This ability to change conductivity with the amount of applied voltage is used for amplifying or switching electronic signals. A MOSFET is based on the modulation of charge concentration by a metal-oxide-semiconductor (MOS) capacitance between a body electrode and a gate electrode located above the body and insulated from all other device regions by a gate dielectric layer. Compared to the MOS capacitor, the MOSFET includes two additional terminals (source and drain), each connected to individual highly doped regions that are separated by the body region. These regions can be either p or n type, but they are both of the same type, and of opposite type to the body region. The source and drain (unlike the body) are highly doped as signified by a “+” sign after the type of doping.

If the MOSFET is an n-channel or nMOS FET, then the source and drain are n+ regions and the body is a p region. If the MOSFET is a p-channel or pMOS FET, then the source and drain are p+ regions and the body is an n region. The source is so named because it is the source of the charge carriers (electrons for n-channel, holes for p-channel) that flow through the channel; similarly, the drain is where the charge carriers leave the channel.

As used herein, the term “fin field-effect transistor (FinFET)” refers to a MOSFET transistor built on a substrate where the gate is placed on two or three sides of the channel, forming a double-or triple-gate structure. FinFET devices have been given the generic name FinFETs because the channel region forms a “fin” on the substrate. FinFET devices have fast switching times and high current density.

As used herein, the term “gate all-around (GAA),” is used to refer to an electronic device, e.g., a transistor, in which the gate material surrounds the channel region on all sides. The channel region of a GAA transistor may include nanowires or nano-slabs, or nano-sheets, bar-shaped channels, or other suitable channel configurations known to one of skill in the art. In one or more embodiments, the channel region of a GAA device has multiple horizontal nanowires or horizontal bars vertically spaced, making the GAA transistor a stacked horizontal gate-all-around (hGAA) transistor.

As used herein, the term “nanowire” refers to a nanostructure, with a diameter on the order of a nanometer (10⁻⁹ meters). Nanowires can also be defined as the ratio of the length to width being greater than 1000. Alternatively, nanowires can be defined as structures having a thickness or diameter constrained to tens of nanometers or less and an unconstrained length. Nanowires are used in transistors and some laser applications, and, in one or more embodiments, are made of semiconducting materials, metallic materials, insulating materials, superconducting materials, or molecular materials. In one or more embodiments, nanowires are used in transistors for logic CPU, GPU, MPU, and volatile (e.g., DRAM) and non-volatile (e.g., NAND) devices.

Embodiments of the present disclosure advantageously provide methods of preventing metal oxide formation during formation of molybdenum-containing layers. Some embodiments advantageously provide methods of forming molybdenum-containing layers having reduced resistivity. The molybdenum-containing layers of one or more embodiments can advantageously be used in MOL and/or BEOL processes. In particular, the molybdenum-containing layers of one or more embodiments can advantageously be used in logic and/or memory applications.

The molybdenum-containing layers of one or more embodiments can advantageously be used as low resistivity electrical connections in the form of vertical interconnects and/or horizontal interconnects through which current flows, as vias between adjacent metal layers, and/or as contacts between a first metal layer and one or more devices on a substrate.

Interconnects comprise metal lines that transfer current within the same device layer, and metal vias that transfer current between layers. These lines and vias are formed with a conductive metal, including, but not limited to, copper (Cu), cobalt (Co), ruthenium (Ru), or molybdenum (Mo) in gaps formed within a microelectronic device. The molybdenum-containing layers of one or more embodiments can advantageously be used as a conductive metal gapfill material in lines and/or vias in interconnect fabrication processes. In specific embodiments, one or more metal lines and/or metal vias comprises a molybdenum-containing layer according to one or more embodiments, and one or more metal lines and/or metal vias comprises a different conductive metal, such as a copper (Cu) or cobalt (Co).

Embodiments of the present disclosure can advantageously extend metal gapfill applications to advanced nodes, such as enabling molybdenum (Mo) reflow in 3nm node, 2 nm node, 1.4 nm node, and beyond. Contact area is significantly reduced per each smaller node, driving up interconnect resistance. In one or more embodiments, the microelectronic devices described herein comprise at least one top interconnect structure that is interconnected to at least one bottom interconnect structure. Embodiments of the disclosure provide microelectronic devices and methods of manufacturing microelectronic devices that improve performance of interconnects, for example, reducing via resistivity at the interconnect.

The fabrication of three-dimensional (3D)-NAND devices includes the formation of alternating silicon oxide (e.g., SiO₂) layers and silicon nitride (e.g., Si₃N₄) layers. After the formation of the stack of alternating layers, the silicon nitride layers are selectively etched to form recesses that are ultimately filled with a conductive material. In one or more embodiments, the recesses in the 3D-NAND devices are ultimately filled with the molybdenum-containing layer of one or more embodiments.

The molybdenum-containing layers of one or more embodiments can advantageously be used in a DRAM device. The molybdenum-containing layers of one or more embodiments can advantageously be used in a NAND device. The molybdenum-containing layers of one or more embodiments may be used in the fabrication of a backside power delivery network (BSPDN) of a gate-all-around (GAA) device.

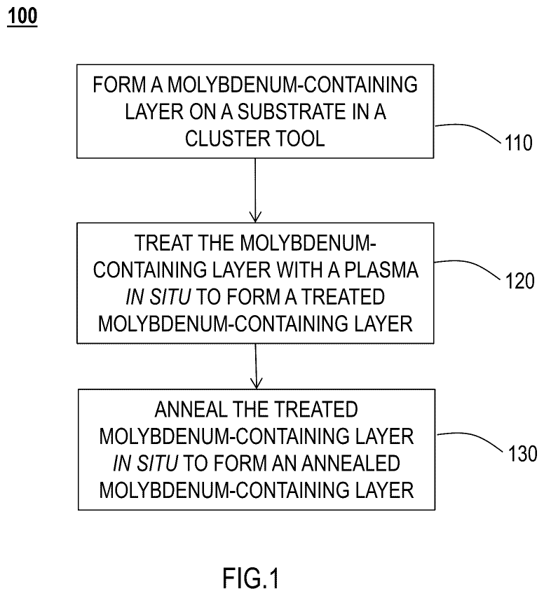

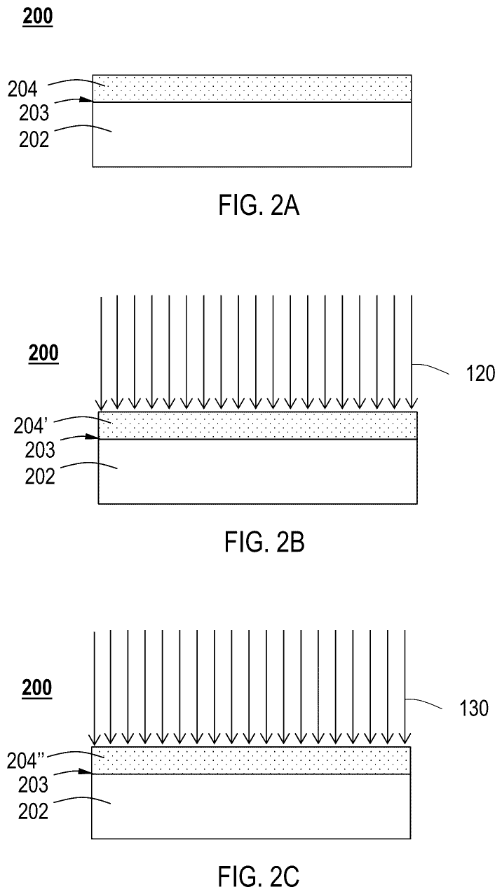

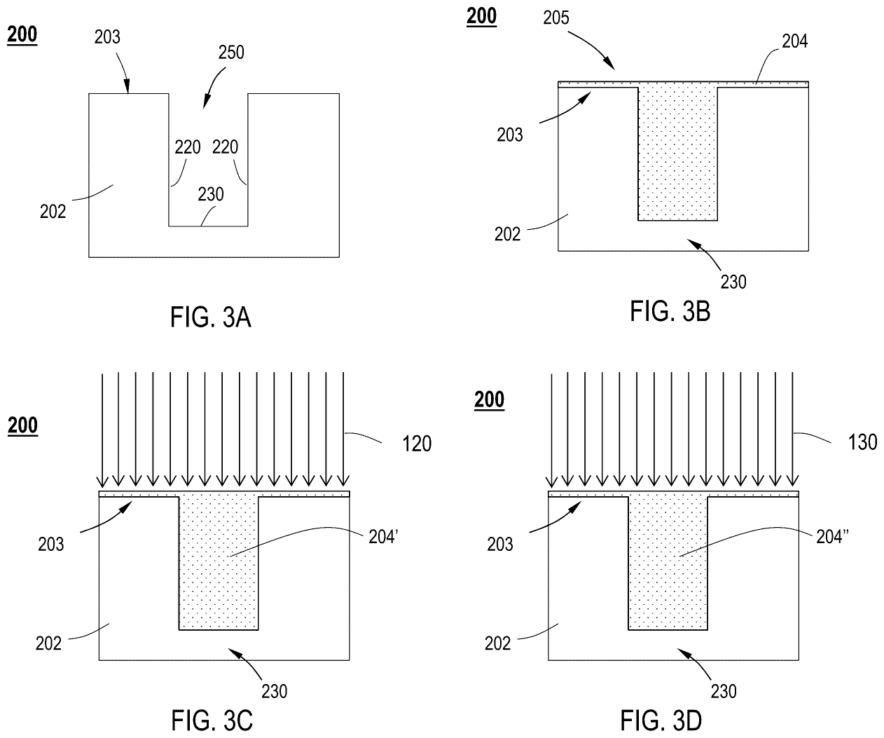

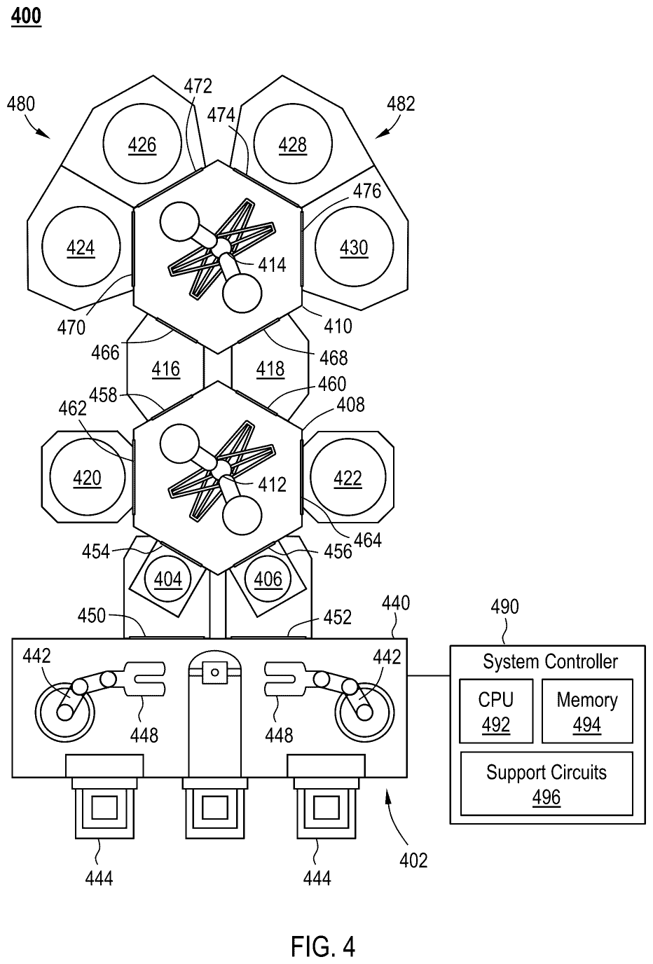

Embodiments of the disclosure are described herein with reference to FIG. 1, FIGS. 2A-2C, FIGS. 3A-3D, and FIG. 4. FIG. 1 is a process flow diagram of a method 100, e.g., a processing method and/or a method of manufacturing a semiconductor device 200, as claimed. FIGS. 2A-2C and FIGS. 3A-3D illustrate stages of manufacture of the semiconductor device 200 during the method 100. FIG. 4 illustrates a multi-chamber processing system, e.g., a cluster tool 400, in which the methods, e.g., method 100, can be performed and the devices, e.g., semiconductor device 200, can be manufactured.

The methods of one or more embodiments, e.g., method 100, are part of a semiconductor device fabrication process. It will be appreciated by the skilled artisan that any additional operations needed to complete the fabrication of any of the disclosed semiconductor devices are known to the skilled artisan and are within the scope of the present disclosure without undue experimentation.

Referring to FIG. 1, the method 100 comprises, at operation 110, forming a molybdenum-containing layer 204 on a substrate 202 in a cluster tool 400. At operation 120, the method 100 comprises treating the molybdenum-containing layer 204 with a plasma in situ to form a treated molybdenum-containing layer 204′. At operation 130, the method 100 comprises annealing the treated molybdenum-containing layer 204′ in situ to form an annealed molybdenum-containing layer 204″. As described herein, keeping the method 100 under vacuum (in situ) advantageously ensures that no oxide is introduced/formed on the substrate 202 during the method 100.

In one or more embodiments, the method 100 comprises operation 110, operation 120, and operation 130. In one or more embodiments, the method 100 consists essentially of operation 110, operation 120, and operation 130. In one or more embodiments, the method 100 consists of operation 110, operation 120, and operation 130.

Referring to FIGS. 2A-2C and FIGS. 3A-3D, a portion of the semiconductor device 200 is shown during stages of manufacture. In one or more embodiments, the substrate 202 is a wafer, for example, a semiconductor substrate.

FIG. 2A illustrates a cross-sectional schematic view of the molybdenum-containing layer 204 formed directly on a top surface 203 of the substrate 202 in accordance with operation 110 of the method 100. FIG. 2B illustrates a cross-sectional schematic view of treating the molybdenum-containing layer 204 of FIG. 2A with a plasma in situ to form a treated molybdenum-containing layer 204′ in accordance with operation 120 of the method 100. FIG. 2C illustrates a cross-sectional schematic view of annealing the treated molybdenum-containing layer 204′ of FIG. 2B in situ to form an annealed molybdenum-containing layer 204″ in accordance with operation 130 of the method 100.

FIG. 3A illustrates a cross-sectional schematic view of the substrate 202 including at least one feature 250 defining a gap having sidewalls 220 and a bottom 230. The Figures show substrates 202 having a single feature for illustrative purposes; however, those skilled in the art will understand that there can be more than one feature. As used herein, the term “feature” means any intentional surface irregularity. Suitable examples of features include but are not limited to trenches which have a top, two sidewalls and a bottom, or peaks which have a top and two sidewalls. Features can have any suitable aspect ratio (ratio of the depth of the feature to the width of the feature). In some embodiments, the aspect ratio is greater than or equal to about 5:1, 10:1, 15:1, 20:1, 25:1, 30:1, 35:1 or 40:1.

In some embodiments, the at least one feature 250 defines a cylindrical via that, when filled with metal, transfers current between layers, and lines that transfer current within the same device layer. In some embodiments, the at least one feature 250 defines the gap. In some embodiments, the gap defines a via portion and a line portion.

The at least one feature 250 may be comprised of any suitable material. In one or more embodiments, the sidewalls 220 comprises a low-κ dielectric material. In one or more embodiments, the sidewalls 220 comprise silicon oxide (SiOₓ). In one or more embodiments, the sidewalls 220 comprise SiOₓH_{y}(CH_{z}). Further embodiments provide that the sidewalls 220 comprise porous or carbon-doped SiOₓ. In some embodiments, the sidewalls 220 comprise a porous or carbon-doped SiOₓ layer with a κ value less than about 5.

In one or more embodiments, the bottom 230 comprises a different material than the sidewalls 220. In one or more embodiments, the bottom 230 comprises a metallic material. In one or more embodiments, the bottom 230 comprises one or more of ruthenium (Ru), copper (Cu), cobalt (cobalt), molybdenum (Mo), tantalum (Ta), or tungsten (W). In one or more embodiments, the bottom 230 comprises one or more of copper (Cu), cobalt (cobalt), molybdenum (Mo), or tungsten (W).

FIG. 3B illustrates a cross-sectional schematic view of the molybdenum-containing layer 204 filling the gap of the substrate 202 of FIG. 3A in accordance with operation 110 of the method 100. FIG. 3C illustrates a cross-sectional schematic view of treating the molybdenum-containing layer 204 of FIG. 3B with a plasma in situ to form a treated molybdenum-containing layer 204′ in accordance with operation 120 of the method 100. FIG. 3D illustrates a cross-sectional schematic view of annealing the treated molybdenum-containing layer 204′ of FIG. 3C in situ to form an annealed molybdenum-containing layer 204″ in accordance with operation 130 of the method 100.

In one or more embodiments, the molybdenum-containing layer 204 filling the gap is substantially free of seams and/or voids or free of seams and/or voids. As used in this regard, “substantially free” means that less than about 5%, including less than about 4%, less than about 3%, less than about 2%, less than about 1%, less than about 0.5%, and less than about 0.1% of the total composition of the molybdenum-containing layer 204 an atomic basis, comprises seams and/or voids. Advantageously, in one or more embodiments, the molybdenum-containing layer 204 is free of seams and/or voids.

Referring to FIGS. 1, 2A, and 3B, in accordance with operation 110 of the method 100, the molybdenum-containing layer 204 is formed by chemical vapor deposition (CVD) or atomic layer deposition (ALD). In some embodiments, the molybdenum-containing layer 204 is formed by chemical vapor deposition (CVD). In some embodiments, the molybdenum-containing layer 204 is formed by atomic layer deposition (ALD).

In some embodiments, the molybdenum-containing layer 204 is formed by exposing the substrate 202 to a molybdenum-containing precursor and a reactant.

The molybdenum-containing precursor may be any suitable precursor. In some embodiments, the molybdenum-containing precursor comprises an organometallic precursor that includes molybdenum (Mo), such as, for example, Bis(1-methylbenzene)molybdenum. In some embodiments, the molybdenum-containing precursor comprises one or more of molybdenum boride (MoB), molybdenum pentachloride (MoCl₅), or molybdenum dioxide dichloride (MoO₂Cl₂).

The reactant may include any suitable reactant to form a pure molybdenum-containing layer, e.g., the molybdenum-containing layer 204. As used herein, a “pure molybdenum-containing layer” is a layer that comprises greater than or equal to about 95%, 98%, 99%, 99.5%, or 99.9% molybdenum (Mo), on an atomic basis. In one or more embodiments, the reactant comprises hydrogen (H₂).

In some embodiments, the processing conditions for forming the molybdenum-containing layer 204 may be controlled and may be varied depending on the composition of the molybdenum-containing precursor. The molybdenum-containing layer 204 can be formed to a predetermined thickness, and the pre-determined thickness may vary depending on the particular application which the molybdenum-containing layer 204 is used.

The molybdenum-containing layer 204 has a first resistivity value in a range of from greater than or equal to 100 μΩ-cm to less than or equal to 500 μΩ-cm. As will be explained herein, the molybdenum-containing layer 204 is treated with a plasma in situ to reduce the first resistivity value.

Referring to FIGS. 1, 2B, and 3C, in accordance with operation 120 of the method 100, the molybdenum-containing layer 204 is treated with a plasma in situ for a time period in a range of from 0.1 seconds to 2 seconds to reduce the first resistivity value and to form a treated molybdenum-containing layer 204′ having a second resistivity value.

In some embodiments, the processing conditions for generating the plasma used to treat the molybdenum-containing layer 204 may be controlled and may be varied depending on the composition of the molybdenum-containing precursor and/or the composition of the plasma. The plasma exposure (operation 120 of method 100) can occur at any suitable temperature, frequency, pressure, and power.

The plasma used to treat the molybdenum-containing layer 204 may be generated by any suitable plasma source. In one or more embodiments, the plasma used to treat the molybdenum-containing layer 204 is generated by one or more of an inductively coupled plasma (ICP) source, a capacitively coupled plasma (CCP) source, a microwave source, or a remote plasma source.

For example, the plasma may range in frequency from about 2 megahertz (MHz) to about 162 MHz or above. For example, non-limiting frequencies such as 2 MHz, 13.56 MHz, 27.12 MHz, 40.68 MHz, 60 MHz, or 162 MHz can be used.

The plasma exposure (operation 120 of method 100) may be performed at any suitable pressure. In one or more embodiments, the plasma exposure (operation 120 of method 100) is performed at a pressure in a range of from 1 Torr to 3 Torr.

The plasma power of various embodiments is in a range of about 25 Watts to about 500 Watts, in a range of from about 25 Watts to about 400 Watts, in a range of from about 50 Watts to about 400 Watts, or in a range of from about 100 Watts to about 400 Watts.

The plasma exposure duration of one or more embodiments is a time period in a range of from 0.1 seconds to 2 seconds. In one or more embodiments, the plasma exposure duration is 2 seconds. In one or more embodiments, the plasma exposure duration is 1.8 seconds. In one or more embodiments, the plasma exposure duration is 1.5 seconds. In one or more embodiments, the plasma exposure duration is 1.3 seconds. In one or more embodiments, the plasma exposure duration is 1 second. In one or more embodiments, the plasma exposure duration is 0.8 seconds. In one or more embodiments, the plasma exposure duration is 0.5 seconds. In one or more embodiments, the plasma exposure duration is 0.3 seconds. In one or more embodiments, the plasma exposure duration is 0.1 seconds.

In one or more embodiments, the plasma is comprised of hydrogen (H₂). In one or more embodiments, the plasma is comprised of hydrogen (H₂) that is diluted by 1 to 90 vol % with an inert gas. In specific embodiments, the inert gas comprises any inert gas, including, but not limited to, one or more of neon (Ne), xenon (Xe), hydrogen (H₂), and argon (Ar) gas.

Referring to FIGS. 1, 2C, and 3D, in accordance with operation 130 of the method 100, the treated molybdenum-containing layer 204′ is annealed in situ to reduce the second resistivity value and to form an annealed molybdenum-containing layer 204″ having a third resistivity value that is in a range of from 50% to 90% less than the first resistivity value.

It has been found exposing metallic materials to air can result in a thin layer of metal oxide being formed on the surface of the metal. This surface layer of metal oxide can interfere with subsequent processing steps and increase resistivity of the metal layer. For example, when a substrate having a molybdenum-containing layer formed thereon is exposed to air during transfer of the substrate to an annealing chamber ex situ, a thin layer of molybdenum oxide forms on the molybdenum-containing layer. The metal oxide layer and its increased resistivity works a goal of annealing processes: to reduce resistivity.

Advantageously, in accordance with operation 130 of the method 100, the treated molybdenum-containing layer 204′ is annealed in situ to reduce the second resistivity value and to form an annealed molybdenum-containing layer having a third resistivity value that is in a range of from 50% to 90% less than the first resistivity value. Advantageously, a thin layer of metal oxide (e.g., molybdenum oxide) is not formed because the method 100 is performed without breaking vacuum.

The annealing according to operation 130 of the method 100 may include any suitable heating process. In one or more embodiments, the annealing according to operation 130 of the method 100 is performed at a temperature in a range of from 200° C. to 1000° C. In one or more embodiments, the annealing according to operation 130 of the method 100 is performed for a time in a range of from 5 seconds to 20 minutes.

In one or more embodiments, the annealing according to operation 130 of the method 100 comprises a rapid thermal process (RTP). In one or more embodiments, the RTP is performed in a hydrogen (H₂) ambient environment. In one or more embodiments, the annealing according to operation 130 of the method 100 comprises annealing the substrate 202 on a pedestal heater. In one or more embodiments, the annealing according to operation 130 of the method 100 comprises annealing the substrate 202 on a resistive heater.

Advantageously, the annealed molybdenum-containing layer 204″ has a third resistivity value that is in a range of from 50% to 90% less than the first resistivity value. In specific embodiments, the third resistivity value is, for example, less than or equal to 50 μΩ-cm, less than or equal to 40 μΩ-cm, or less than or equal to 30 μΩ-cm.

One or more embodiments are directed to a method of manufacturing a microelectronic device. The method comprises: forming a dielectric layer on a substrate, the dielectric layer including at least one feature defining a gap having sidewalls and a bottom; forming a blocking layer on the bottom; selectively depositing a barrier layer on the sidewalls; optionally, selectively depositing a metal liner on the barrier layer, on the sidewalls; removing the blocking layer; and performing a gap fill process to fill the gap with a gapfill material comprising molybdenum (Mo), e.g., the molybdenum-containing layers described herein. It will be appreciated by the skilled artisan that any additional operations needed to complete the fabrication of any of the disclosed semiconductor devices e.g., microelectronic devices, are known to the skilled artisan and are within the scope of the present disclosure without undue experimentation.

FIG. 4 illustrates a schematic top-view diagram of an example of a multi-chamber processing system, e.g., a cluster tool 400, according to embodiments of the present disclosure. The cluster tool 400 generally includes a factory interface 402, load lock chambers 404, 406, transfer chambers 408, 410 with respective transfer robots 412, 414, holding chambers 416, 418, and processing chambers 420, 422, 424, 426, 428, 430. As detailed herein, wafers in the cluster tool 400 can be processed in and transferred between the various chambers without exposing the wafers to an ambient environment exterior to the cluster tool 400 That is, the wafers in the cluster tool 400, e.g., the substrate 202, is processed in and transferred between the various chambers in situ. For example, the wafers can be processed in and transferred between the various chambers in a low pressure (e.g., less than or equal to about 300 Torr) or vacuum environment without breaking the low pressure or vacuum environment between various processes performed on the wafers in the cluster tool 400. Accordingly, the cluster tool 400 provides an integrated system for some processing of wafers, e.g., semiconductor substrates such as the substrate 202.

In the illustrated example of FIG. 4, the factory interface 402 includes a docking station 440 and factory interface robots 442 to facilitate transfer of wafers. The docking station 440 is configured to accept one or more front opening unified pods (FOUPs) 444. In some examples, each factory interface robot 442 generally comprises a blade 448 disposed on one end of the respective factory interface robot 442 configured to transfer the wafers from the factory interface 402 to the load lock chambers 404, 406.

The load lock chambers 404, 406 have respective ports 450, 452 coupled to the factory interface 402 and respective ports 454, 456 coupled to the transfer chamber 408. The transfer chamber 408 further has respective ports 458, 460 coupled to the holding chambers 416, 418 and respective ports 462, 464 coupled to processing chambers 420, 422. Similarly, the transfer chamber 410 has respective ports 466, 468 coupled to the holding chambers 416, 418 and respective ports 470, 472, 474, 476 coupled to processing chambers 424, 426, 428, 430. The ports 454, 456, 458, 460, 462, 464, 466, 468, 470, 472, 474, 476 can be, for example, slit valve openings with slit valves for passing wafers therethrough by the transfer robots 412, 414 and for providing a seal between respective chambers to prevent a gas from passing between the respective chambers. Generally, any port is open for transferring a wafer therethrough. Otherwise, the port is closed.

The load lock chambers 404, 406, transfer chambers 408, 410, holding chambers 416, 418, and processing chambers 420, 422, 424, 426, 428, 430 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, a factory interface robot 442 transfers a wafer from a FOUP 444 through a port 450 or 452 to a load lock chamber 404 or load lock chamber 406. The gas and pressure control system then pumps down the load lock chamber 404 or load lock chamber 406. The gas and pressure control system further maintains the transfer chambers 408, 410 and holding chambers 416, 418 with an interior low pressure or vacuum environment (which may include an inert gas). Hence, the pumping down of the load lock chamber 404 or load lock chamber 406 facilitates passing the wafer between, for example, the atmospheric environment of the factory interface 402 and the low pressure or vacuum environment of the transfer chamber 408.

With the wafer in the load lock chamber 404 or load lock chamber 406 that has been pumped down, the transfer robot 412 transfers the wafer from the load lock chamber 404 or load lock chamber 406 into the transfer chamber 408 through the port 454 or 456. The transfer robot 412 is then capable of transferring the wafer to and/or between any of the processing chambers 420, 422 through the respective ports 462, 464 for processing and the holding chambers 416, 418 through the respective ports 458, 460 for holding to await further transfer. Similarly, the transfer robot 414 is capable of accessing the wafer in the holding chamber 416 or 418 through the port 466 or 468 and is capable of transferring the wafer to and/or between any of the processing chambers 424, 426, 428, 430 through the respective ports 470, 472, 474, 476 for processing and the holding chambers 416, 418 through the respective ports 466, 468 for holding to await further transfer. The transfer and holding of the wafer within and among the various chambers can be in the low pressure or vacuum environment provided by the gas and pressure control system.

The processing chambers 420, 422, 424, 426, 428, 430 can be any appropriate chamber for processing a wafer. In some embodiments, one or more of the processing chambers 420, 422, 424, 426, 428, 430 can be used to form a molybdenum-containing layer using a vapor deposition technique, such as chemical vapor deposition (CVD) or atomic layer deposition (ALD). In some embodiments, one or more of the processing chambers 420, 422, 424, 426, 428, 430 can be used to treat the molybdenum-containing layer with a plasma in situ, such as by plasma-enhanced chemical vapor deposition (PECVD) or plasma-enhanced atomic layer deposition (PEALD). In some embodiments, one or more of the processing chambers 420, 422, 424, 426, 428, 430 can be used to anneal the treated molybdenum-containing layer in situ.

A system controller 490 is coupled to the cluster tool 400 for controlling the cluster tool 400 or components thereof. For example, the system controller 490 may control the operation of the cluster tool 400 using a direct control of the chambers 404, 406, 408, 416, 418, 410, 420, 422, 424, 426, 428, 430 of the cluster tool 400 or by controlling controllers associated with the chambers 404, 406, 408, 416, 418, 410, 420, 422, 424, 426, 428, 430. In operation, the system controller 490 enables data collection and feedback from the respective chambers to coordinate performance of the cluster tool 400.

The system controller 490 generally includes a central processing unit (CPU) 492, memory 494, and support circuits 496. The CPU 492 may be one of any form of a general-purpose processor that can be used in an industrial setting. The memory 494, or non-transitory computer-readable medium, is accessible by the CPU 492 and may be one or more of memory such as random-access memory (RAM), read only memory (ROM), floppy disk, hard disk, or any other form of digital storage, local or remote. The support circuits 496 are coupled to the CPU 492 and may comprise cache, clock circuits, input/output subsystems, power supplies, and the like. The various methods disclosed herein may generally be implemented under the control of the CPU 492 by the CPU 492 executing computer instruction code stored in the memory 494 (or in memory of a particular process chamber) as, for example, a software routine. When the computer instruction code is executed by the CPU 492, the CPU 492 controls the chambers to perform processes in accordance with the various methods.

Other processing systems can be in other configurations. For example, more or fewer processing chambers may be coupled to a transfer apparatus. In the illustrated example, the transfer apparatus includes the transfer chambers 408, 410 and the holding chambers 416, 418. In other examples, more or fewer transfer chambers (e.g., one transfer chamber) and/or more or fewer holding chambers (e.g., no holding chambers) may be implemented as a transfer apparatus in a processing system.

Another aspect of the disclosure pertains to a non-transitory computer readable medium including instructions, that, when executed by a controller of a processing system, causes the processing system to perform operations of the methods described herein. In one embodiment, a non-transitory computer readable medium including instructions, that, when executed by a controller of a processing system, e.g., the system controller 490 of the cluster tool 400 of FIG. 4, causes the cluster tool 400 to perform operations of the methods described herein with respect to FIGS. 1, 2A-2C, and 3A-3D.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A processing method comprising:
forming a molybdenum-containing layer on a substrate in a cluster tool, the molybdenum-containing layer having a first resistivity value in a range of from greater than or equal to 100 μΩ-cm to less than or equal to 500 μΩ-cm;
treating the molybdenum-containing layer with a plasma in situ for a time period in a range of from 0.1 seconds to 2 seconds to reduce the first resistivity value and to form a treated molybdenum-containing layer having a second resistivity value; and
annealing the treated molybdenum-containing layer in situ to reduce the second resistivity value and to form an annealed molybdenum-containing layer having a third resistivity value that is in a range of from 50% to 90% less than the first resistivity value.

2. The processing method of claim 1, wherein the molybdenum-containing layer is formed by chemical vapor deposition (CVD) or atomic layer deposition (ALD).

3. The processing method of claim 1, wherein the molybdenum-containing layer is formed by exposing the substrate to a molybdenum-containing precursor and a reactant.

4. The processing method of claim 3, wherein the molybdenum-containing precursor comprises an organometallic precursor that includes molybdenum (Mo), molybdenum pentachloride (MoCl₅), or molybdenum dioxide dichloride (MoO₂Cl₂).

5. The processing method of claim 1, wherein the plasma is generated by one or more of an inductively coupled plasma (ICP) source, a capacitively coupled plasma (CCP) source, a microwave source, or a remote plasma source.

6. The processing method of claim 5, wherein the plasma is comprised of hydrogen (H₂).

7. The processing method of claim 6, wherein the plasma is comprised of hydrogen (H₂) that is diluted by 1 to 90 vol % with an inert gas.

8. The processing method of claim 1, wherein the annealing is performed at a temperature in a range of from 200° C. to 1000° C.

9. The processing method of claim 1, wherein the annealing is performed for a time period in a range of from 5 seconds to 20 minutes.

10. The processing method of claim 1, wherein the annealing comprises a rapid thermal process (RTP).

11. The processing method of claim 1, wherein the third resistivity value is less than or equal to 30 μΩ-cm.

12. The processing method of claim 1, wherein the substrate includes at least one feature defining a gap having sidewalls comprising a low-κ dielectric material and a bottom comprising a metallic material and the molybdenum-containing layer fills the gap.

13. A method of manufacturing a semiconductor device, the method comprising:
forming a molybdenum-containing layer on a substrate in a cluster tool, the substrate including at least one feature defining a gap having sidewalls comprising a low-κ dielectric material and a bottom comprising a metallic material, the molybdenum-containing layer filling the gap and having a first resistivity value in a range of from greater than or equal to 100 μΩ-cm to less than or equal to 500 μΩ-cm;
treating the molybdenum-containing layer with a plasma in situ for a time period in a range of from 0.1 seconds to 2 seconds to reduce the first resistivity value and to form a treated molybdenum-containing layer having a second resistivity value; and
annealing the treated molybdenum-containing layer in situ to reduce the second resistivity value and to form an annealed molybdenum-containing layer having a third resistivity value that is in a range of from 50% to 90% less than the first resistivity value, wherein the annealing is performed at a temperature in a range of from 200° C. to 1000° C. for a time in a range of from 5 seconds to 20 minutes.

14. The method of claim 13, wherein the molybdenum-containing layer is formed by exposing the substrate to a molybdenum-containing precursor and a reactant.

15. The method of claim 14, wherein the molybdenum-containing precursor comprises an organometallic precursor that includes molybdenum (Mo), molybdenum pentachloride (MoCl₅), or molybdenum dioxide dichloride (MoO₂Cl₂).

16. The method of claim 13, wherein the plasma is generated by one or more of an inductively coupled plasma (ICP) source, a capacitively coupled plasma (CCP) source, a microwave source, or a remote plasma source.

17. The method of claim 13, wherein the plasma is comprised of hydrogen (H₂) or hydrogen (H₂) that is diluted by 1 to 90 vol % with an inert gas.

18. The method of claim 13, wherein the annealing comprises a rapid thermal process (RTP).

19. The method of claim 13, wherein the third resistivity value is less than or equal to 30 μΩ-cm.

20. The method of claim 13, wherein the semiconductor device comprises a logic device or a memory device.
